(19) United States
(12) Patent Application Publication
(10) Pub. No.: US 2011/0278529 A1
(43) Pub. Date: Nov. 17, 2011

(54) MEMORY EMPLOYING DIAMOND-LIKE CARBON RESISTIVITY-SWITCHABLE MATERIAL AND METHODS OF FORMING THE SAME

(76) Inventor: Huiwen Xu, Sunnyvale, CA (US)

(21) Appl. No.: 12/780,564

(22) Filed: May 14, 2010

(51) Int. Cl. H01L 45/00; H01L 21/20

(52) U.S. Cl. 257/2; 438/382; 257/E45.001; 257/E21.09

(57) ABSTRACT

In a first aspect, a method of forming a memory cell having a diamond like carbon (DLC) resistivity-switching material is provided that includes (1) forming a metal-insulator-metal (MIM) stack that includes (a) a first conductive layer; (b) a DLC switching layer above the first conductive layer; and (c) a second conductive layer above the DLC switching layer; (2) forming a compressive dielectric liner along a sidewall of the MIM stack; and (3) forming a steering element coupled to the MIM stack. Numerous other aspects are provided.

### TECHNICAL FIELD

This invention relates to microelectronic devices, such as non-volatile memories, and more particularly to a memory employing a diamond-like carbon (“DLC”) resistivity-switchable material, and methods of forming the same.

### BACKGROUND

Non-volatile memories formed from carbon-based reversible resistance-switching elements are known. For example, U.S. patent application Ser. No. 11/968,154, filed Dec. 31, 2007, titled “Memory Cell That Employs A Selectively Fabricated Carbon Nano-Tube Reversible Resistance Switching Element And Methods Of Forming The Same” (the “'154 Application”), which is hereby incorporated by reference herein in its entirety for all purposes, describes a rewriteable non-volatile memory cell that includes a diode coupled in series with a carbon-based reversible resistivity-switching material.

However, fabricating memory devices from carbon-based switching materials is technically challenging, and improved methods of forming memory devices that employ carbon-based switching materials are desirable.

### SUMMARY

In a first aspect of the invention, a method of forming a memory cell having a DLC resistivity-switching material is provided, the method including: (1) forming a metal-insulator-metal (“MIM”) stack that includes: (a) a first conductive layer; (b) a DLC switching layer above the first conductive layer; and (c) a second conductive layer above the DLC switching layer; (2) forming a compressive dielectric liner along a sidewall of the MIM stack; and (3) forming a steering element coupled to the MIM stack.

In second aspect of the invention, a method of forming a memory cell is provided, the method including: (1) forming an MIM stack having: (a) a first conductive layer; (b) a DLC switching layer above the first conductive layer; and (c) a second conductive layer above the DLC switching layer; (2) forming a compressive dielectric liner along a sidewall of the MIM stack; (3) forming compressive dielectric gap fill material around the MIM stack; and (4) forming a steering element coupled to the MIM stack.

In a third aspect of the invention, a memory cell is provided that includes: (1) an MIM stack having: (a) a first conductive layer; (b) a DLC switching layer above the first conductive layer; and (c) a second conductive layer above the DLC switching layer; (2) a compressive dielectric liner along a sidewall of the MIM stack; and (3) a steering element coupled to the MIM stack.

In a fourth aspect of the invention, a memory cell is provided that includes: (1) an MIM stack, the MIM stack having: (a) a first conductive layer; (b) a DLC switching layer above the first conductive layer; and (c) a second conductive layer above the DLC switching layer; (2) a compressive dielectric liner along a sidewall of the MIM stack; (3) a compressive dielectric gap fill material around the MIM stack; and (4) a steering element coupled to the MIM stack.

In a fifth aspect of the invention, a method is provided, the method including: (1) forming an MIM stack by: (a) forming a first conductive layer; (b) forming a DLC switching layer above the first conductive layer; and (c) forming a second conductive layer above the DLC switching layer; and (2) forming a compressive dielectric liner along a sidewall of the MIM stack.

In a sixth aspect of the invention, an apparatus is provided that includes: (1) a MIM stack including: (a) a first conductive layer; (b) a DLC switching layer above the first conductive layer; and (c) a second conductive layer above the DLC switching layer; and (2) a compressive dielectric liner along a sidewall of the MIM stack. Numerous other aspects are provided.

Other features and aspects of this invention will become more fully apparent from the following detailed description, the appended claims and the accompanying drawings.

### BRIEF DESCRIPTION OF THE DRAWINGS

Features of the present invention can be more clearly understood from the following detailed description considered in conjunction with the following drawings, in which the same reference numerals denote the same elements throughout, and in which:

FIG. 1 is a diagram of an exemplary memory cell in accordance with this invention;

FIG. 2A is a simplified perspective view of an exemplary memory cell in accordance with this invention;

FIG. 2B is a cross sectional, perspective view of a portion of the memory cell of FIG. 2A;

FIG. 2C is a simplified perspective view of a portion of a first exemplary memory level formed from a plurality of the memory cells of FIG. 2A;

FIG. 2D is a simplified perspective view of a portion of a first exemplary three-dimensional memory array in accordance with this invention;

FIG. 2E is a simplified perspective view of a portion of a second exemplary three-dimensional memory array in accordance with this invention;

FIG. 3A is a cross-sectional view of a first additional exemplary embodiment of a memory cell in accordance with this invention;

FIG. 3B is a cross-sectional view of a second additional exemplary embodiment of a memory cell in accordance with this invention;

FIGS. 4A-4G illustrate cross-sectional views of a portion of a substrate during an exemplary fabrication of a single memory level in accordance with this invention; and

FIGS. 5A-5C are cross-sectional views of MIM stacks in accordance with this invention.

### DETAILED DESCRIPTION

Some carbon-based materials have been shown to exhibit reversible resistivity-switching properties that may be suitable for use in non-volatile memories. As used herein, carbon-based read-writeable or “switching” materials generally may include one or more of graphene, graphite, carbon nano-tubes (collectively referred to herein as “graphitic carbon”), amorphous carbon containing nanocrystalline graphene, DLC, silicon carbide, boron carbide and other crystalline forms of carbon, and may also include secondary materials.

Carbon-based switching materials have demonstrated memory switching properties on lab-scale devices with a 100× separation between ON and OFF states and mid-to-high range resistance changes. Such a separation between ON and OFF states renders carbon-based switching materials viable candidates for memory cells in which the carbon-based switching material is coupled in series with vertical diodes, thin film transistors or other steering elements.

For example, an MIM stack formed from a carbon-based switching material sandwiched between two metal or otherwise conducting layers may serve as a resistance-switching element for a memory cell. For example, a CNT MIM stack may be integrated in series with a diode or transistor to create a read-writable memory device as described, for example, in the '154 Application.

Attempts to implement carbon-based switching materials in memory devices have proven technically challenging. For instance, carbon-based switching material may be hard to switch and may require current densities that exceed the capabilities of the electrodes and/or steering element used with the switching material. Further, some carbon-based switching material may outgas, shrink and peel during device fabrication.

In exemplary embodiments of this invention, MIM stacks and/or memory cells and arrays are formed with DLC resistivity-switching materials. DLC material may have an increased resistivity relative to other carbon-based materials, making DLC material more compatible with the selection (steering) device used during switching of the DLC material.

In particular, DLC is a material that may be fabricated in two different types: (1) amorphous carbon, or (2) hydrogenated amorphous carbon with a high fraction of metastable sp³ carbon bonding. DLC may have a combination of sp² and sp³ bonded carbon, and also may have carbon-hydrogen bonds. The sp³ content in DLC materials may range from about 30-100%, and the hydrogen content in DLC materials may range from about 0-50% or more. Although not wanting to be bound by any particular theory, it is believed that conductive sp²-like filaments form in the DLC material during switching, and provide a current path through the predominantly sp³ bonded carbon material.

DLC may be fabricated using a variety of different processing techniques. For example, amorphous carbon may be produced by sputtering (e.g., unbalanced magnetron sputtering), mass selected ion beam deposition (“MSIB”), filtered cathodic vacuum arc (“FCVA”), and pulsed laser ablation deposition (“PLD”). Additionally, hydrogenated amorphous carbon may be produced by plasma-enhanced chemical vapor deposition (“PECVD”), reactive sputtering of graphite in an atmosphere including hydrogen, and ion beam deposition from a hydrocarbon gas precursor. Other techniques may be used to form DLC.

High temperature processing used during memory array fabrication, such as temperatures at or above about 500° C., may break carbon-hydrogen bonds within a DLC material, causing outgassing of hydrogen from the DLC material and reconfiguration of carbon-carbon bonds from sp³ to sp². This may cause the resistivity of the DLC material to decrease and also cause the DLC material to shrink and peel from layers in contact with the DLC material. Such a decrease in resistivity may render the DLC material incompatible with the steering element used to switch the DLC material.

Embodiments of the invention reduce and/or compensate for hydrogen outgassing in DLC materials and stabilize higher resistivity sp³ bonds within DLC materials. For example, outgassing of hydrogen and/or conversion of sp³ bonds to sp² bonds may be mitigated by one or more of: (1) increasing adhesion of DLC material to adjacent surfaces such as top and bottom electrodes; (2) exerting compressive stress on DLC material; and (3) providing a hydrogen rich local atmosphere for DLC material.

Increasing adhesion of DLC material to adjacent layers may help encapsulate or otherwise prevent hydrogen outgassing from the DLC material. Adhesion may be improved, for example, through selection of suitable electrode material and/or the use of adhesion layers.

Increasing compressive stress on DLC material may help stabilize sp³ carbon bonds in the DLC material, thereby preventing formation of lower resistivity sp² bonds. In addition, compressive stress on DLC material may facilitate switching of sp²-like filaments back to sp³ bonded carbon. In some embodiments, a compressive dielectric material and/or liner may be employed to exert compressive stress on DLC material and also seal or otherwise prevent hydrogen from outgassing from the DLC material.

A hydrogen rich local environment may be achieved by increasing hydrogen content of DLC material and surrounding layers (such as in any compressive dielectric liner that may be used), and/or by employing a hydrogen rich environment during device fabrication (particularly during annealing).

Implementation of these techniques may allow DLC materials to maintain relatively high resistivity levels during memory cell fabrication. In this manner, the current levels used during switching of DLC material may remain compatible with the current capabilities of a steering element employed with the DLC material.

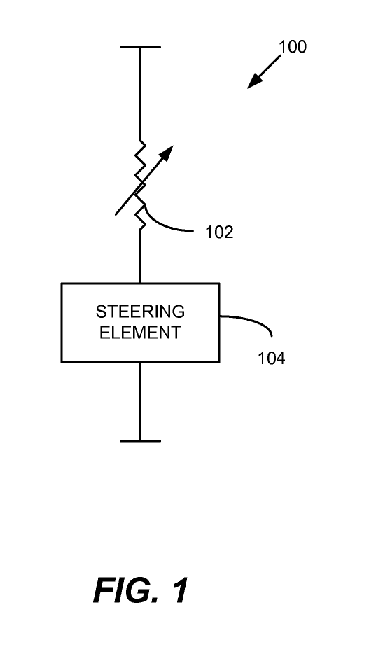

These and other embodiments of the invention are described below with reference to FIGS. 1-5C.

### Exemplary Inventive Memory Cell

FIG. 1 is a schematic illustration of an exemplary memory cell 100 in accordance with this invention. Memory cell 100 includes a reversible resistivity-switching material 102 coupled to a steering element 104. Reversible resistivity-switching material 102 has a resistivity that may be reversibly switched between two or more states.

For example, reversible resistivity-switching material 102 may be in an initial, low-resistivity state upon fabrication. Upon application of a first voltage and/or current, the material is switchable to a high-resistivity state. Application of a second voltage and/or current may return reversible resistivity-switching material 102 to a low-resistivity state. Alternatively, reversible resistivity-switching material 102 may be in an initial, high-resistivity state upon fabrication that is reversibly switchable to a low-resistivity state upon application of the appropriate voltage(s) and/or current(s). When used in a memory cell, one resistivity state may represent a binary “0,” whereas another resistivity state may represent a binary “1,” although more than two data/resistivity states may be used.

Numerous reversible resistivity-switching materials and operation of memory cells employing reversible resistivity-switching materials are described, for example, in U.S. patent application Ser. No. 11/125,939, filed May 9, 2005 and titled “Rewriteable Memory Cell Comprising A Diode And A Resistance Switching Material,” which is hereby incorporated by reference herein in its entirety for all purposes.

Steering element 104 may include a thin film transistor, a diode, a metal-insulator-metal tunneling current device, or another similar steering element that exhibits non-ohmic conduction by selectively limiting the voltage across and/or the current flow through reversible resistivity-switching material 102. In this manner, memory cell 100 may be used as part of a two or three dimensional memory array and data may be written to and/or read from memory cell 100 without affecting the state of other memory cells in the array. In some embodiments, steering element 104 may be omitted, and memory cell 100 may be used with a remotely located steering element.

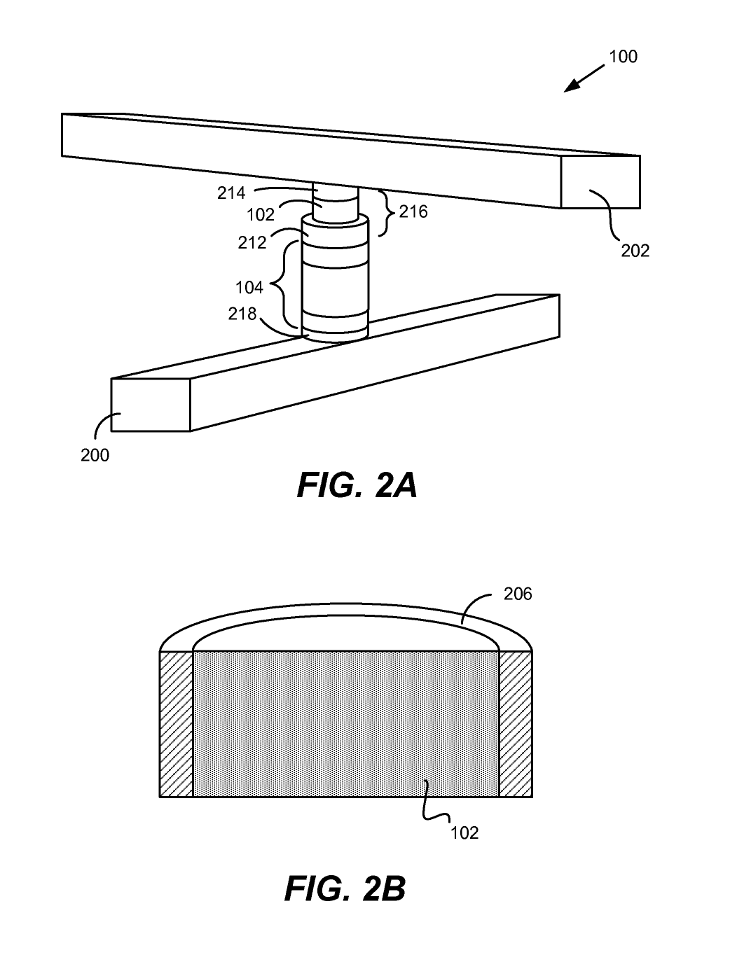

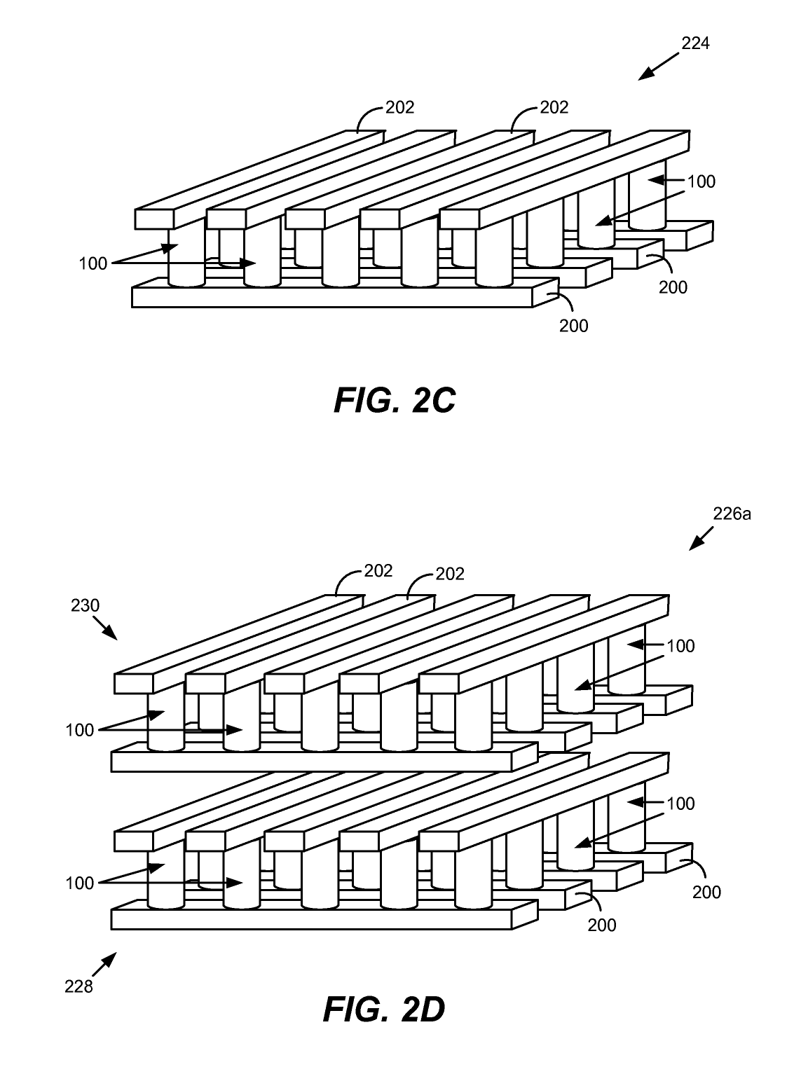

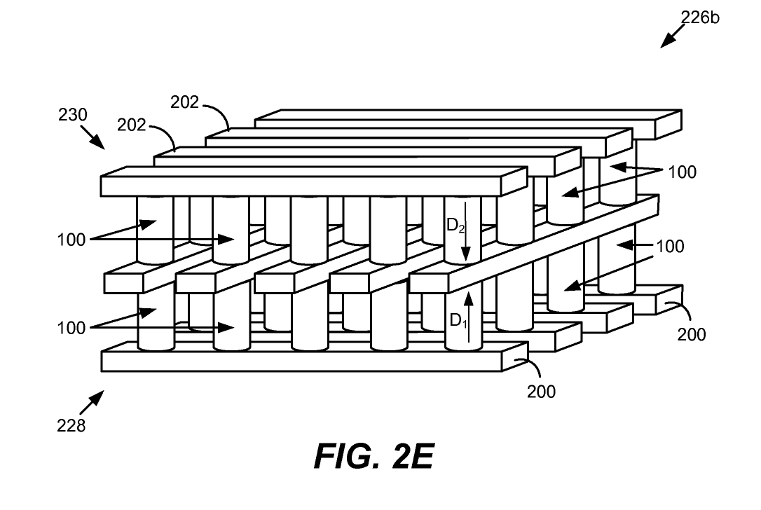

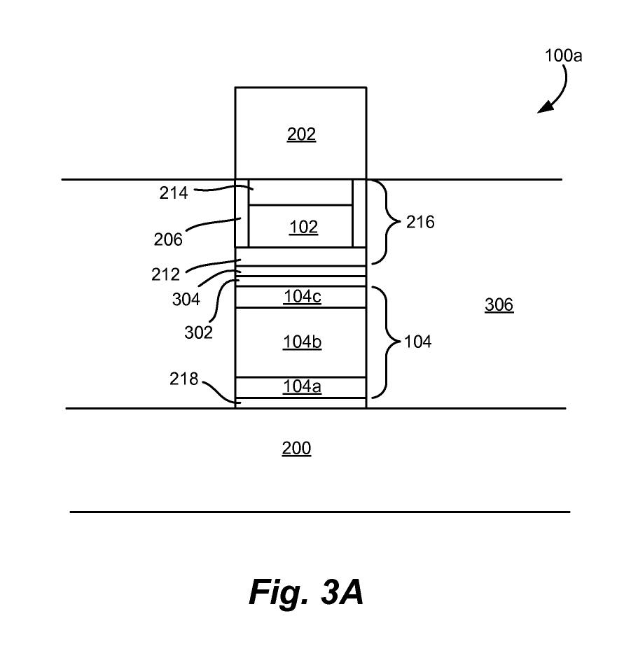

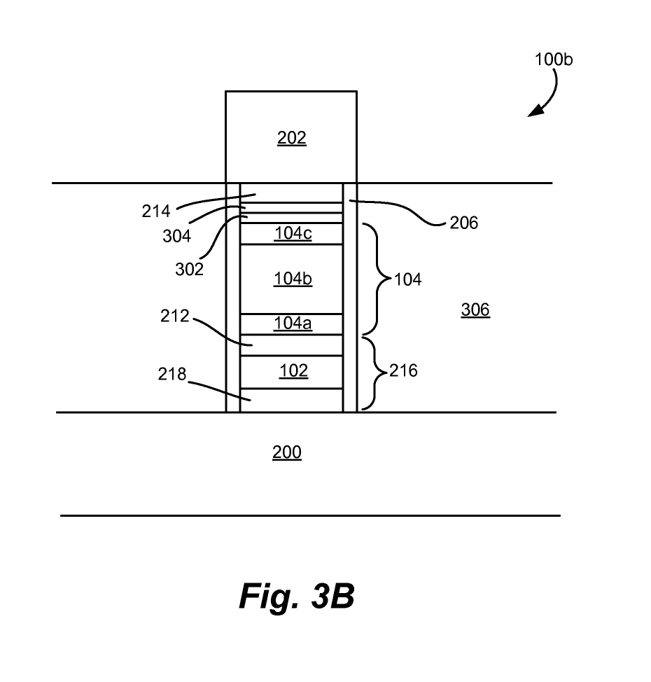

Exemplary embodiments of memory cell 100, reversible resistivity-switching material 102 and steering element 104 are described below with reference to FIGS. 2A-2E and 3A-3B.

### Exemplary Embodiments of Memory Cells and Memory Arrays

FIG. 2A is a simplified perspective view of an exemplary embodiment of a memory cell 100 in accordance with this invention in which steering element 104 is a diode. Memory cell 100 includes a carbon-based reversible resistivity-switching material 102 (“C-based switching material 102”) coupled in series with a diode 104 between a first conductor 200 and a second conductor 202.

In the embodiment of FIG. 2A, a compressive dielectric liner (shown in FIG. 2B as liner 206) is employed to exert a compressive force on C-based switching material 102, and in some embodiments, to serve as a local source of hydrogen for C-based switching material 102 as described further below. Use of such a dielectric liner also reduces a cross-sectional area of C-based switching material 102 relative to the cross sectional area of diode 104. For example, FIG. 2B is a cross sectional view of a thin compressive dielectric liner 206 that surrounds C-based switching material 102. Other C-based switching material shapes/configurations may be used. For example, in some embodiments of this invention, liner 206 may surround C-based switching material and diode 104.

In some embodiments, a barrier layer 212 may be formed between C-based switching material 102 and diode 104, and a barrier layer 214 may be formed between C-based switching material 102 and second conductor 202, forming an MIM stack 216 that may serve as a reversible resistance-switching element. An additional barrier layer 218 may be formed between diode 104 and first conductor 200.

Barrier layers 212, 214 and 218 may include titanium, titanium nitride, tantalum, tantalum nitride, tungsten, tungsten nitride, molybdenum, or another similar barrier layer. Barrier layer 214 may be separate from or part of second conductor 202 and barrier layer 218 may be separate from or part of first conductor 200. In one particular embodiment, barrier layer 212 may be titanium, titanium silicide or a titanium/titanium silicide stack as will be described further below with reference to FIG. 3A.

In accordance with one or more embodiments of this invention, C-based switching material 102 may be DLC. As previously stated, DLC material may have an increased resistivity relative to other carbon-based materials, making DLC material more compatible with the steering element (e.g., diode 104) used during switching of the DLC material.

DLC materials may have a combination of sp² and sp³ bonded carbon, and also may have carbon-hydrogen bonds. The sp³ content in DLC materials may range from about 30-100%, and the hydrogen content in DLC materials may range from about 0-50% or more. Outgassing of hydrogen from a DLC layer during high temperature processing may reduce the DLC layer's resistivity, and cause the DLC layer to shrink and/or peel.

To reduce the affects of high temperature processing used during memory array fabrication on C-based switching material 102 when a DLC layer is used for C-based switching material 102, one or more of the following may be performed: (1) increasing adhesion of C-based switching material 102 to adjacent surfaces such as barrier layers 212 and 214; (2) exerting compressive stress on C-based switching material 102; and (3) providing a hydrogen rich local atmosphere for C-based switching material 102.

Increasing adhesion of C-based switching material 102 to adjacent layers may help encapsulate or otherwise prevent hydrogen outgassing from C-based switching material 102. For example, C-based switching material 102 may include interface regions that have increased sp³ content relative to the remainder of C-based switching material 102 to improve adhesion and/or compensate for conversion of sp³ bonds to sp² bonds during subsequent high temperature processing such as thermal anneals. Materials having improved adhesion to carbon, such as a metal silicide, carbon nitride, degenerately doped silicon, or tungsten and/or tungsten nitride (not separately shown) may be placed in direct contact with C-based switching material 102 within MIM stack 216.

Exerting compressive stress on C-based switching material 102 may help stabilize sp³ carbon bonds in C-based switching material 102, thereby preventing formation of lower resistivity sp² bonds. In some embodiments, C-based switching material 102 itself may be formed with a high compressive stress level. In the same or alternative embodiments, a compressive dielectric liner 206 and/or a compressive dielectric gap fill material (described below with reference to FIGS. 3A-3B) may be employed to exert compressive stress on C-based switching material 102 and also seal or otherwise prevent hydrogen from outgassing from C-based switching material 102. For example, in some embodiments, compressive dielectric liner 206 may include a compressive oxygen-poor dielectric, such as compressive silicon nitride, and a compressive dielectric gap fill material such as a compressive oxide may be used.

A hydrogen rich local environment may be achieved by increasing hydrogen content of C-based switching material 102 and/or surrounding layers (such as in any compressive dielectric liner 206 that may be used), and/or by employing a hydrogen rich environment during device fabrication (particularly during annealing). These and other embodiments are described further below with reference to FIGS. 3A-5C.

Diode 104 may include any suitable diode such as a vertical polycrystalline p-n or p-i-n diode, whether upward pointing with an n-region above a p-region of the diode or downward pointing with a p-region above an n-region of the diode. In some embodiments, diode 104 may be a Schottky diode.

First conductor 200 and/or second conductor 202 may include any suitable conductive material such as tungsten, any appropriate metal, heavily doped semiconductor material, a conductive silicide, a conductive silicide-germanide, a conductive germanide, or the like. In the embodiment of FIG. 2A, first and second conductors 200 and 202, respectively, are rail-shaped and extend in different directions (e.g., substantially perpendicular to one another). Other conductor shapes and/or configurations may be used. In some embodiments, barrier layers, adhesion layers, antireflection coatings and/or the like (not shown) may be used with first conductor 200 and/or second conductor 202 to improve device performance and/or aid in device fabrication.

FIG. 2C is a simplified perspective view of a portion of a first memory level 224 formed from a plurality of memory cells 100, such as memory cells 100 of FIG. 2A. For simplicity, C-based switching material 102, diode 104, and barrier layers 212, 214 and 218 are not separately shown. Memory array 224 is a “cross-point” array including a plurality of bit lines (second conductors 202) and word lines (first conductors 200) to which multiple memory cells are coupled (as shown). Other memory array configurations may be used, as may multiple levels of memory.

FIG. 2D is a simplified perspective view of a portion of a monolithic three dimensional memory array 226a that includes a first memory level 228 positioned below a second memory level 230. Memory levels 228 and 230 each include a plurality of memory cells 100 in a cross-point array. Persons of ordinary skill in the art will understand that additional layers (e.g., an interlevel dielectric) may be present between first and second memory levels 228 and 230, but are not shown in FIG. 2D for simplicity. Other memory array configurations may be used, as may additional levels of memory. In the embodiment of FIG. 2D, all diodes may “point” in the same direction, such as upward or downward depending on whether p-i-n diodes having a p-doped region on the bottom or top of the diodes are employed, simplifying diode fabrication.

In some embodiments, the memory levels may be formed as described in U.S. Pat. No. 6,952,030, titled “High-Density Three-Dimensional Memory Cell,” which is hereby incorporated by reference herein in its entirety for all purposes. For instance, the second conductors of a first memory level may be used as the first conductors of a second memory level that is positioned above the first memory level as shown in FIG. 2E. In such embodiments, the diodes on adjacent memory levels preferably point in opposite directions as described in U.S. patent application Ser. No. 11/692,151, filed Mar. 27, 2007 and titled “Large Array Of Upward Pointing P-I-N Diodes Having Large And Uniform Current,” which is hereby incorporated by reference herein in its entirety for all purposes. For example, as shown in memory array 226b in FIG. 2E, the diodes of first memory level 228 may be upward pointing diodes as indicated by arrow D1 (e.g., with p regions at the bottom of the diodes), whereas the diodes of second memory level 230 may be downward pointing diodes as indicated by arrow D2 (e.g., with n regions at the bottom of the diodes), or vice versa.

A monolithic three dimensional memory array is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in Leedy, U.S. Pat. No. 5,915,167, titled “Three Dimensional Structure Memory.” The substrates may be thinned or removed from the memory levels before bonding, but as the memory levels are initially formed over separate substrates, such memories are not true monolithic three dimensional memory arrays.

FIG. 3A is a cross-sectional view of a first exemplary embodiment of memory cell 100 of FIG. 1, in accordance with the invention, referred to as memory cell 100a. In particular, memory cell 100a includes MIM stack 216, diode 104, and first and second conductors 200 and 202, respectively. MIM stack 216 includes C-based switching material 102, barrier layer 212 and barrier layer 214.

In the embodiment shown, MIM stack 216 is located above diode 104. However, in other embodiments, MIM stack 216 may be located beneath diode 104 as described below with reference to FIG. 3B. In some embodiments, diode 104 may be located remotely from MIM stack 216 (e.g., not between first and second conductors 200 and 202).

In the embodiment of FIG. 3A, diode 104 may be a vertical p-n or p-i-n diode, which may either point upward or downward. In some embodiments, diode 104 may be formed from a polycrystalline semiconductor material such as polysilicon, a polycrystalline silicon-germanium alloy, polygermanium or any other suitable material. For example, diode 104 may include a heavily doped n+ polysilicon region 104a, a lightly doped or an intrinsic (unintentionally doped) polysilicon region 104b above n+ polysilicon region 104a, and a heavily doped p+ polysilicon region 104c above intrinsic region 104b. It will be understood that the locations of the n+ and p+ regions may be reversed.

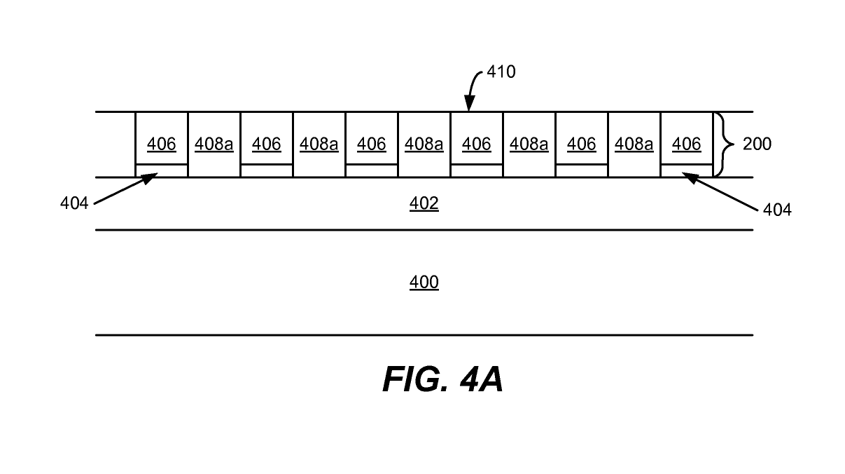

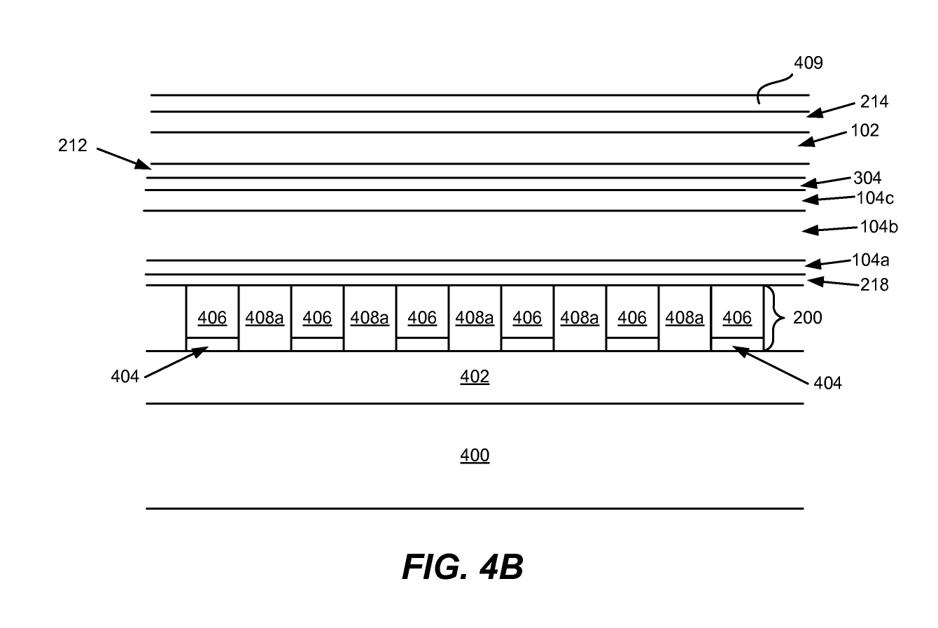

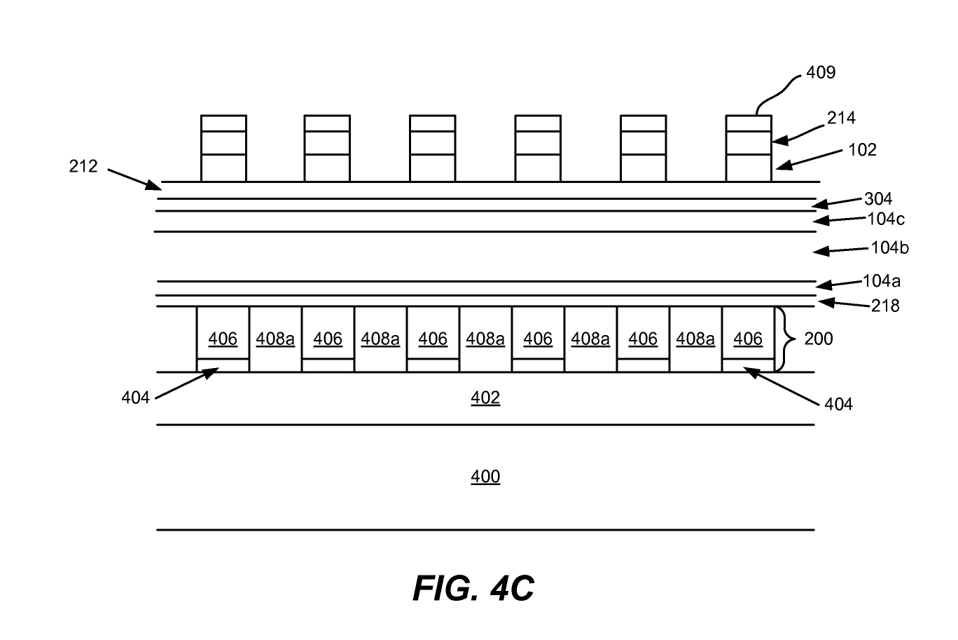

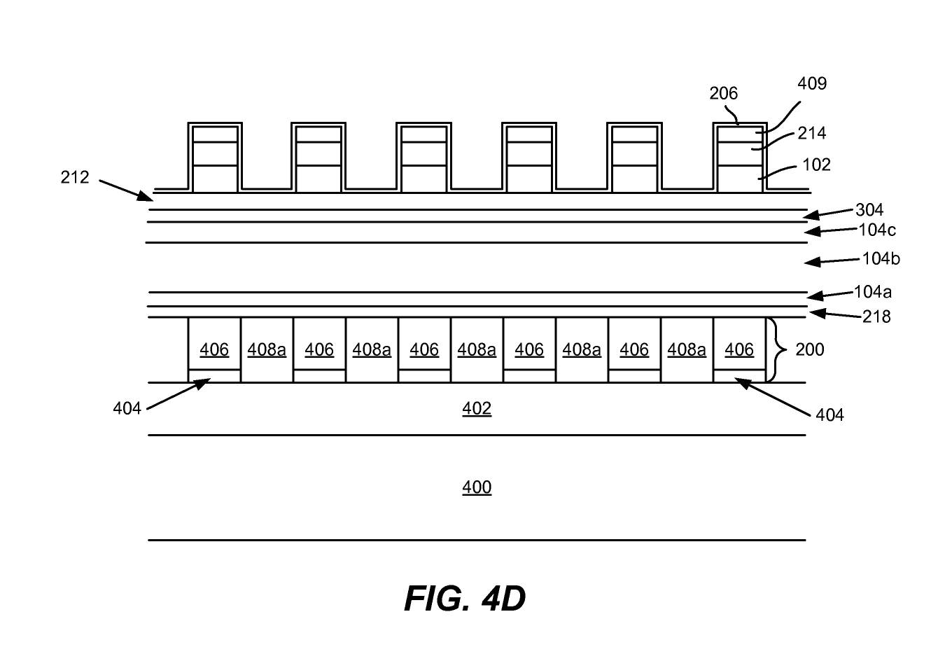

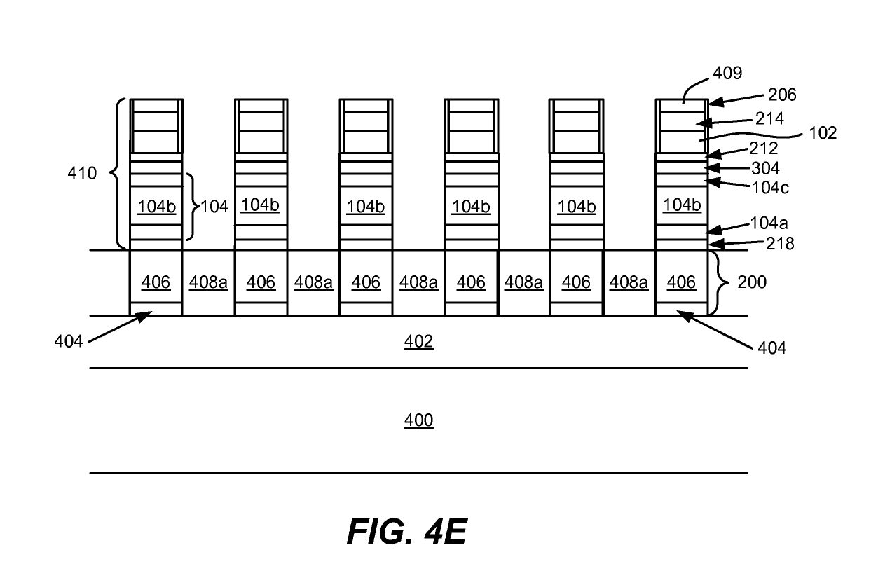

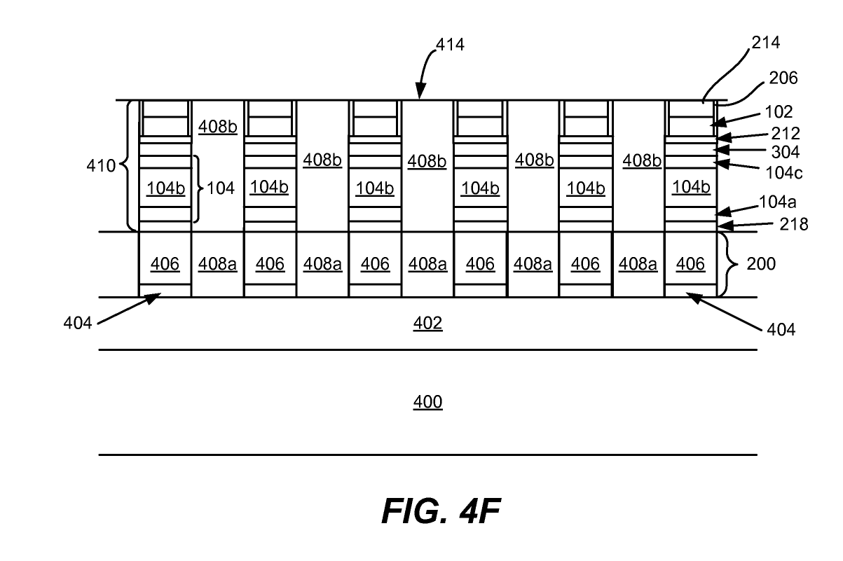

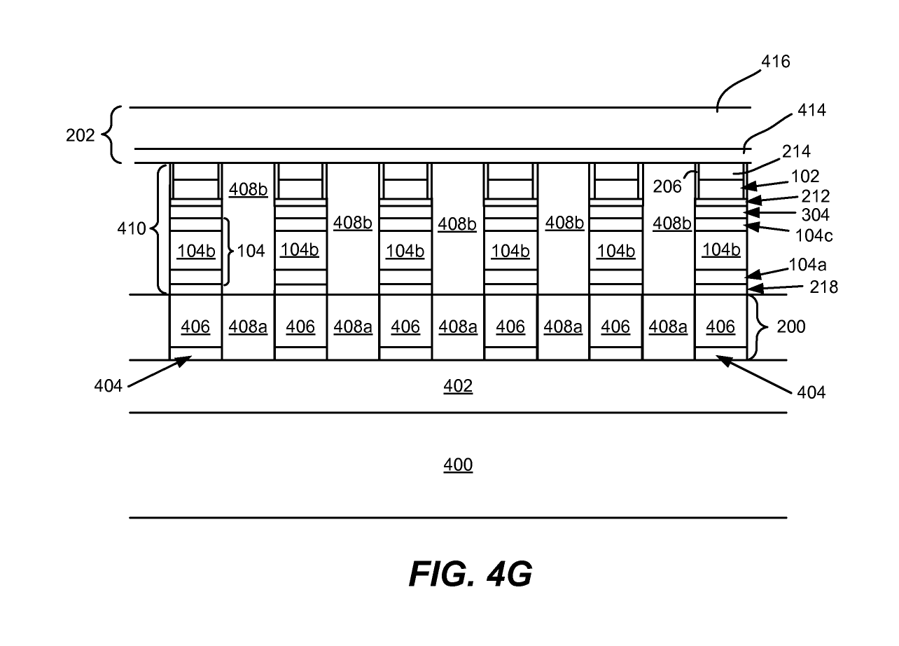

If diode 104 is fabricated from deposited silicon (e.g., amorphous or polycrystalline), a silicide layer 302 may be formed on diode 104 to place the deposited silicon in a low resistivity state, as fabricated. Such a low resistivity state allows for easier programming of memory cell 100a as a large voltage is not required to switch the deposited silicon to a low resistivity state. For example, a silicide-forming metal layer 304 such as titanium or cobalt may be deposited on p+ polysilicon region 104c and used to form silicide layer 302 (as described below). In some embodiments, barrier layer 212 may be eliminated and C-based switching material 102 may be in direct contact with silicide layer 302 and/or silicide-forming metal layer 304. Additional process details for such an embodiment are described below with reference to FIGS. 4A-4G.

As shown in FIG. 3A, C-based switching material 102 is contacted by compressive dielectric liner 206 which exerts compressive stress on and encapsulates C-based switching material 102. In addition, a compressive gap fill dielectric material 306 further exerts compressive stress on and encapsulates C-based switching material 102. As previously mentioned, in some embodiments of this invention, compressive dielectric liner 206 may surround C-based switching material and diode 104. Exemplary compressive dielectric liner and compressive gap fill materials include compressive silicon nitride and compressive silicon dioxide, respectively, although other compressive dielectric materials may be used.

FIG. 3B is a cross-sectional view of an alternative exemplary embodiment of memory cell 100 of FIG. 1, in accordance with the invention, referred to as memory cell 100b. Memory cell 100b of FIG. 3B is similar to memory cell 100a of FIG. 3A with the exception that diode 104 is located above MIM stack 216. In such an embodiment, compressive dielectric liner 206 may extend along the entire length of the pillar formed by diode 104 and MIM stack 216. In alternative embodiments, compressive dielectric liner 206 may extend only along MIM stack 206.

### Exemplary Fabrication Processes for Memory Cells

Referring now to FIGS. 4A-4G, a first exemplary method of forming a memory level in accordance with this invention is described. In particular, FIGS. 4A-4G illustrate an exemplary method of forming a memory level including memory cells 100 of FIG. 2A. As will be described below, the first memory level includes a plurality of memory cells that each include a steering element and a DLC, C-based switching material coupled to the steering element. Additional memory levels may be fabricated above the first memory level (as described previously with reference to FIGS. 2D-2E). A memory level including memory cells 100a of FIG. 3A or memory cells 100b of FIG. 3B may be formed using a similar method.

With reference to FIG. 4A, substrate 400 is shown as having already undergone several processing steps. Substrate 400 may be any suitable substrate such as a silicon, germanium, silicon-germanium, undoped, doped, bulk, silicon-on-insulator (“SOI”) or other substrate with or without additional circuitry. For example, substrate 400 may include one or more n-well or p-well regions (not shown).

Isolation layer 402 is formed above substrate 400. In some embodiments, isolation layer 402 may be a layer of silicon dioxide, silicon nitride, silicon oxynitride or any other suitable insulating layer.

Following formation of isolation layer 402, an adhesion layer 404 is formed over isolation layer 402 (e.g., by physical vapor deposition or another method). For example, adhesion layer 404 may be about 20 to about 500 angstroms, and preferably about 100 angstroms, of titanium nitride or another suitable adhesion layer such as titanium, tantalum, tantalum nitride, tungsten, tungsten nitride, molybdenum, combinations of one or more adhesion layers, or the like. Other adhesion layer materials and/or thicknesses may be employed. In some embodiments, adhesion layer 404 may be optional.

After formation of adhesion layer 404, a conductive layer 406 is deposited over adhesion layer 404. Conductive layer 406 may include any suitable conductive material such as tungsten or another appropriate metal, heavily doped semiconductor material, a conductive silicide, a conductive silicide-germanide, a conductive germanide, or the like deposited by any suitable method (e.g., chemical vapor deposition (“CVD”), physical vapor deposition (“PVD”), etc.). In at least one embodiment, conductive layer 106 may comprise about 200 to about 2500 angstroms of tungsten. Other conductive layer materials and/or thicknesses may be used.

Following formation of conductive layer 406, adhesion layer 404 and conductive layer 406 are patterned and etched. For example, adhesion layer 404 and conductive layer 406 may be patterned and etched using conventional lithography techniques, with a soft or hard mask, and wet or dry etch processing. In at least one embodiment, adhesion layer 404 and conductive layer 406 are patterned and etched to form substantially parallel, substantially co-planar first conductors 200. Exemplary widths for first conductors 200 and/or spacings between first conductors 200 range from about 200 to about 2500 angstroms, although other conductor widths and/or spacings may be used.

After first conductors 200 have been formed, a dielectric layer 408a is formed over substrate 400 to fill the voids between first conductors 200. For example, approximately 3000-7000 angstroms of silicon dioxide may be deposited on substrate 400 and planarized using chemical mechanical polishing or an etchback process to form a planar surface 410. Planar surface 410 includes exposed top surfaces of first conductors 200 separated by dielectric material (as shown). Other dielectric materials such as silicon nitride, silicon oxynitride, low k dielectrics, etc., and/or other dielectric layer thicknesses may be used. Exemplary low k dielectrics include carbon doped oxides, silicon carbon layers, or the like.

In other embodiments of the invention, first conductors 200 may be formed using a damascene process in which dielectric layer 408a is formed, patterned and etched to create openings or voids for first conductors 200. The openings or voids then may be filled with adhesion layer 404 and conductive layer 406 (and/or a conductive seed, conductive fill and/or barrier layer if needed). Adhesion layer 404 and conductive layer 406 then may be planarized to form planar surface 410. In such an embodiment, adhesion layer 404 will line the bottom and sidewalls of each opening or void.

With reference to FIG. 4B, a barrier layer 218 is formed over planarized top surface 410 of substrate 400. Barrier layer 218 may be about 20 to about 500 angstroms, and preferably about 100 angstroms, of titanium nitride or another suitable barrier layer such as titanium, tantalum, tantalum nitride, tungsten, tungsten nitride, molybdenum, combinations of one or more barrier layers, barrier layers in combination with other layers such as titanium/titanium nitride, tantalum/tantalum nitride or tungsten/tungsten nitride stacks, or the like. Other barrier layer materials and/or thicknesses may be employed.

After deposition of barrier layer 218, deposition of the semiconductor material used to form the diode of each memory cell begins (e.g., diode 104 in FIGS. 1 and 2A). Each diode may be a vertical upward or downward pointing p-n or p-i-n diode as previously described. In some embodiments, each diode is formed from a polycrystalline semiconductor material such as polysilicon, a polycrystalline silicon-germanium alloy, polygermanium or any other suitable material. For convenience, formation of a polysilicon, downward-pointing diode is described herein. It will be understood that other materials and/or diode configurations may be used.

With reference to FIG. 4B, following formation of barrier layer 218, a heavily doped n+ silicon layer 104a is deposited on barrier layer 218. In some embodiments, n+ silicon layer 104a is in an amorphous state as deposited. In other embodiments, n+ silicon layer 104a is in a polycrystalline state as deposited. CVD or another suitable process may be employed to deposit n+ silicon layer 104a. In at least one embodiment, n+ silicon layer 104a may be formed, for example, from about 100 to about 1000 angstroms, preferably about 100 angstroms, of phosphorus or arsenic doped silicon having a doping concentration of about 10²¹ cm⁻³. Other layer thicknesses, doping types and/or doping concentrations may be used. N+ silicon layer 104a may be doped in situ, for example, by flowing a donor gas during deposition. Other doping methods may be used (e.g., implantation).

After deposition of n+ silicon layer 104a, a lightly doped, intrinsic and/or unintentionally doped silicon layer 104b may be formed over n+ silicon layer 104a. In some embodiments, intrinsic silicon layer 104b may be in an amorphous state as deposited. In other embodiments, intrinsic silicon layer 104b may be in a polycrystalline state as deposited. CVD or another suitable deposition method may be employed to deposit intrinsic silicon layer 104b. In at least one embodiment, intrinsic silicon layer 104b may be about 500 to about 4800 angstroms, preferably about 2500 angstroms, in thickness. Other intrinsic layer thicknesses may be used.

A thin (e.g., a few hundred angstroms or less) germanium and/or silicon-germanium alloy layer (not shown) may be formed on n+ silicon layer 104a prior to depositing intrinsic silicon layer 104b to prevent and/or reduce dopant migration from n+ silicon layer 104a into intrinsic silicon layer 104b (as described in U.S. patent application Ser. No. 11/298,331, filed Dec. 9, 2005 and titled “Deposited Semiconductor Structure To Minimize N-Type Dopant Diffusion And Method Of Making,” which is hereby incorporated by reference herein in its entirety for all purposes).

Heavily doped, p-type silicon may be either deposited and doped by ion implantation or may be doped in situ during deposition to form a p+ silicon layer 104c. In some embodiments, a blanket p+ implant may be employed to implant boron a predetermined depth within intrinsic silicon layer 104b. Exemplary implantable molecular ions include BF₂, BF₃, B and the like. In some embodiments, an implant dose of about 1-5×10¹⁵ ions/cm² may be employed. Other implant species and/or doses may be used. Further, in some embodiments, a diffusion process may be employed. In at least one embodiment, the resultant p+ silicon layer 104c has a thickness of about 100-700 angstroms, although other p+ silicon layer sizes may be used.

Following formation of p+ silicon layer 104c, a silicide-forming metal layer 304 is deposited over p+ silicon layer 104c. Exemplary silicide-forming metals include sputter or otherwise deposited titanium or cobalt. In some embodiments, silicide-forming metal layer 304 has a thickness of about 10 to about 200 angstroms, preferably about 20 to about 50 angstroms and more preferably about 20 angstroms. Other silicide-forming metal layer materials and/or thicknesses may be used. A nitride layer (not shown) may be formed at the top of silicide-forming metal layer 304.

A rapid thermal anneal (“RTA”) step may be performed to form silicide regions by reaction of silicide-forming metal layer 304 with p+ region 104c. In some embodiments, the RTA may be performed at about 540° C. for about 1 minute, and causes silicide-forming metal layer 304 and the deposited silicon of diode 104 to interact to form a silicide layer, consuming all or a portion of silicide-forming metal layer 304. Following the RTA step, any residual nitride layer from silicide-forming metal layer 304 may be stripped using a wet chemistry. For example, if silicide-forming metal layer 304 includes a TiN top layer, a wet chemistry (e.g., H₂O:H₂O₂:NH₄OH in a 10:2:1 ratio) may be used to strip any residual TiN.

As described in U.S. Pat. No. 7,176,064, titled “Memory Cell Comprising A Semiconductor Junction Diode Crystallized Adjacent To A Silicide,” which is hereby incorporated by reference herein in its entirety for all purposes, silicide-forming materials such as titanium and/or cobalt react with deposited silicon during annealing to form a silicide layer. The lattice spacing of titanium silicide and cobalt silicide are close to that of silicon, and it appears that such silicide layers may serve as “crystallization templates” or “seeds” for adjacent deposited silicon as the deposited silicon crystallizes (e.g., a silicide layer enhances the crystalline structure of silicon diode 104 during annealing). Lower resistivity silicon thereby is provided. Similar results may be achieved for silicon-germanium alloy and/or germanium diodes.

Following the RTA step and the nitride strip step, in some embodiments, a barrier layer 212 is formed above silicide-forming metal layer 304. Barrier layer 212 may be about 5 to about 800 angstroms, and preferably about 100 angstroms, of titanium nitride or another suitable barrier layer such as titanium, tantalum, tantalum nitride, tungsten, tungsten nitride, molybdenum, combinations of one or more barrier layers, barrier layers in combination with other layers such as titanium/titanium nitride, tantalum/tantalum nitride or tungsten/tungsten nitride stacks, or the like. Other barrier layer materials and/or thicknesses may be employed.

Following formation of barrier layer 212 (if employed), C-based switching material 102 is formed. In one or more embodiments of the invention, C-based switching material 102 is DLC. As stated, DLC is typically amorphous carbon having a combination of sp² and sp³ bonded carbon, as well as carbon-hydrogen bonds. Hydrogen facilitates formation of higher resistivity sp³ carbon-carbon bonds in DLC materials, and hydrogen content in DLC materials generally may range from about 0-50% or more.

A DLC layer that may be used for C-based switching material 102 may be formed by any suitable method. In one exemplary embodiment, PECVD may be employed to form the DLC layer. Other deposition processes may be used to form a DLC layer such as laser ablation, RF or ion sputtering of a graphite target, ion plating, or the like. Table 1 provides PECVD process details for an exemplary low temperature DLC formation process. Other source gases, flow rates, pressures, temperatures, powers and/or spacings may be used. Any C_{X}H_{Y} precursor, or other suitable precursor, may be used with any carrier/dilution gas such as H₂, He, Ar, Xe, Kr, etc. In general, hydrocarbon precursor gas sources may include, but are not limited to, hexane, cyclo-hexane, acetylene, single and double short chain hydrocarbons such as methane, various benzene based hydrocarbons, polycyclic aromatics, aliphatic hydrocarbons, alicyclic hydrocarbons, aromatic hydrocarbons, short chain ester, ethers, and alcohols or a combination thereof.

TABLE 1
EXEMPLARY PROCESS PARAMETERS
FOR DIAMOND-LIKE CARBON LAYER

| PROCESS PARAMETER | BROAD RANGE | NARROW RANGE |
|---|---|---|
| He:CₓH_{y} Ratio | 0.2:1-15:1 | 0.5:1-5:1 |
| PRESSURE (Torr) | 1-10 | 1-5 |
| SUBSTRATE TEMP (° C.) | 200-650 | 300-450 |
| TARGET RF POWER | 0.1-40 | 3.5-24 |
| (WATTS/IN²) | | |
| TARGET-SUBSTRATE | ≧250 | 350 |
| SPACING (mils) | | |

In some embodiments of the invention, the DLC, C-based switching material 102 may have a thickness of about 10-100 angstroms, more generally between about 1-600 angstroms, although other thicknesses may be used. C-based switching material 102 may have a resistivity value between about 1×10⁶-1×10⁸ Ohm-cm, more generally between about 1×10⁵-1×10⁹ Ohm-cm. Other resistivity values may be used.

In one or more embodiments, the DLC, C-based switching material 102 may have a compressive stress level of between about 1-3 GPa, more generally between about 500 Mpa-3 GPa. Hydrogen content may range from about 0-30%, more generally from about 0-50%. Other stress and/or hydrogen levels may be used.

Following formation of C-based switching material 102, barrier layer 214 is formed. Barrier layer 214 may be about 5 to about 800 angstroms, and preferably about 100 angstroms, of titanium nitride or another suitable layer such as titanium, tantalum, tantalum nitride, tungsten, tungsten nitride, molybdenum, combinations of one or more layers, or any other suitable material(s). Other barrier layer thicknesses and/or materials may be used.

In at least one embodiment, a hard mask layer 409, such as about 100-500 nanometers of silicon nitride, silicon oxide or the like, may be deposited over barrier layer 214. Thinner or thicker hard mask layers may be used with smaller critical dimensions and technology nodes. Photoresist may be deposited and patterned using standard photolithography techniques. Hard mask layer 409 then may be etched to expose barrier layer 214 in regions in which barrier layer 214 is to be etched. After etching/patterning of hard mask layer 409, the photoresist may be removed and layers 214 and 102 may be etched, resulting in the structure shown in FIG. 4C. (Note that use of a hard mask reduces exposure of C-based switching material 102 to an oxygen plasma that may be employed during photoresist removal/asking).

In some embodiments, hard mask layer 409 may be formed on top of barrier layer 214, with bottom antireflective coating (“BARC”) on top, then patterned and etched. Similarly, dielectric antireflective coating (“DARC”) may be used as a hard mask. In other embodiments, a metal hard mask (not shown) such as a thick titanium or similar layer may be used as hard mask layer 409. Use of metal hard masks is described, for example, in U.S. patent application Ser. No. 11/444,936, filed 13 May 2006 and titled “Conductive Hard Mask To Protect Patterned Features During Trench Etch,” which is hereby incorporated by reference herein in its entirety for all purposes.

Barrier layer 214 and C-based switching material 102 may be etched using any suitable process. For example, the exemplary etch parameters shown in Table 2 may be used.

TABLE 2
EXEMPLARY ETCH PARAMETERS FOR TiN
BARRIER LAYER AND DLC LAYER

| PROCESS PARAMETER | BARRIER LAYER | CARBON LAYER |
|---|---|---|
| CF₄ FLOW RATE (sccm) | 50-100 | — |
| N₂ FLOW RATE (sccm) | 10-50 | 40-100 |
| Cl₂ FLOW RATE (sccm) | 30-70 | — |
| He FLOW RATE (sccm) | 30-80 | — |
| O₂ FLOW RATE (sccm) | — | 15-50 |
| Ar FLOW RATE (sccm) | — | |
| PRESSURE (mTorr) | 1-20 | 2-8 |
| SOURCE RF POWER | 350-550 | 500-700 |
| (watts) | | |
| BIAS RF POWER (watts) | 60-90 | 130-170 |
| SOURCE RF POWER | 7-11 | 10-14 |
| DENSITY (watts/in²) | | |
| BIAS RF POWER | 1.2-1.8 | 2.6-3.4 |
| DENSITY (watts/in²) | | |

In one particular embodiment, an oxygen plasma may be used to etch C-based switching material 102 (stopping on barrier layer 212, silicide-forming metal layer 304 or diode region 104c).

After barrier layer 214 and C-based switching material 102 have been etched, a thin compressive dielectric liner 206 may be deposited on the exposed sidewalls of barrier layer 214 and C-based switching material 102 as shown in FIG. 4D. For example, a compressive dielectric liner 206 such as silicon nitride may be formed with an oxygen-poor deposition chemistry (e.g., without a high oxygen plasma component) to protect C-based switching material 102.

In some embodiments, compressive dielectric liner 206 may have a compressive stress of at least 2 GPa and in some embodiments at least 3 GPa, although larger or smaller values may be used. Further, in some embodiments, compressive dielectric liner 206 may have a hydrogen content of between about 0-30%, more generally between about 0-50%, although larger or smaller percentages may be present.

In some embodiments, compressive dielectric liner 206 may comprise about 100-300 angstroms, more generally between about 100-600 angstroms, of stoichiometric or non-stoichiometric silicon nitride. However, the structure optionally may comprise other layer thicknesses and/or other materials, such as SiₓC_{y}N_{z} and SiₓO_{y}N_{z} (with low O content), etc., where x, y and z are non-zero numbers resulting in stable compounds.

In one exemplary embodiment, a compressive SiN dielectric sidewall liner 206 may be formed using the process parameters listed in Table 3. Liner film thickness scales linearly with time. Other gas sources, powers, temperatures, pressures, spacings and/or flow rates may be used. Hydrogen may be added to the dielectric sidewall liner deposition chemistry to increase the compressive stress of the formed layer. For example, Table 3 provides exemplary process parameters for formation of a high compressive stress SiN dielectric liner 206 having about 40 atm % or more of hydrogen.

TABLE 3
COMPRESSIVE STRESS
SiN LINER PROCESS PARAMETERS

| | EXEMPLARY | PREFERRED |
|---|---|---|
| PROCESS PARAMETER | VALUE | RANGE |
| SiH₄ Flow Rate (sccm) | 35 | 20-100 |
| NH₃ Flow Rate (sccm) | 80 | 50-500 |
| H₂ Flow Rate (sccm) | 750 | 100-5000 |
| Ar Flow Rate (sccm) | 2300 | 1000-10000 |
| High Frequency RF (W) | 0.08 | 0.05-0.3 |
| LF/HF Power Ratio | 0.08 | 0.75-1 |
| Temperature (° C.) | 400 | 300-650 |
| Spacing (mils) | 325 | 200-500 |
| Pressure (Torr) | 2 | 1-10 |

Other processes may be used to form a compressive dielectric liner, such as high density plasma (“HDP”) deposition with a suitable high frequency bias power.

Following formation of compressive dielectric liner 206, the remaining memory cell layers may be etched down to dielectric layer 408a as shown in FIG. 4E to form pillars 410. Any suitable etch chemistries, and any suitable etch parameters, flow rates, chamber pressures, power levels, process temperatures, and/or etch rates may be used. In some embodiments, compressive dielectric layer 206, barrier layer 212, silicide-forming metal layer 304, diode layers 104a-104c and barrier layer 218 may be patterned using a single etch step. In other embodiments, separate etch steps may be used. The etch proceeds down to dielectric layer 408a.

In alternative embodiments of this invention, C-based switching material 102, barrier layer 212, silicide-forming metal layer 304, diode layers 104a-104c and barrier layer 218 may be patterned using a single etch step, and then compressive dielectric liner 206 may surround the entire etched structure.

Referring again to FIG. 4E, after etching, pillars 410 may be cleaned using a dilute hydrofluoric/sulfuric acid clean. Such cleaning, whether or not PR asking is performed before etching, may be performed in any suitable cleaning tool, such as a Raider tool, available from Semitool of Kalispell, Mont. Exemplary post-etch cleaning may include using ultra-dilute sulfuric acid (e.g., about 1.5-1.8 wt %) for about 60 seconds and ultra-dilute hydrofluoric (“HF”) acid (e.g., about 0.4-0.6 wt %) for 60 seconds. Megasonics may or may not be used.

After pillars 410 have been cleaned, a dielectric layer 408b may be deposited over pillars 410 to fill the voids between pillars 410. For example, approximately 200-10000 angstroms of silicon dioxide may be deposited and planarized using chemical mechanical polishing or an etchback process to remove excess dielectric material 408b and hard mask layer 409 and form a planar surface 414, resulting in the structure illustrated in FIG. 4F. Planar surface 414 includes exposed regions of barrier layer 214 separated by dielectric material 408b (as shown). Other dielectric materials such as silicon nitride, silicon oxynitride, low k dielectrics, etc., and/or other dielectric layer thicknesses may be used.

In some embodiments, the dielectric gap fill layer 408b may comprise a compressive oxide layer having a compressive stress of at least 500 MPa and in some embodiments at least 2 GPa. For example, dielectric gap fill layer 408b may be formed using an ozone/TEOS process, such as the Applied Producer® HARP™ process of Applied Materials, Inc., Santa Clara, Calif. Other deposition techniques also may be used.

In other embodiments, a compressive TEOS film may be used for dielectric layer 408b. Other suitable formation processes for forming compressive dielectric films include low pressure CVD (“LPCVD”), thermal CVD, HDP deposition and the like. Such processes have been used to create compressive films for modulating the electrical properties of metal-oxide-semiconductor (“MOS”) devices, for example.

With reference to FIG. 4G, second conductors 202 may be formed above pillars 410 in a manner similar to the formation of first conductors 200. For example, in some embodiments, one or more barrier layers and/or adhesion layers 414 may be deposited over pillars 410 prior to deposition of a conductive layer 416 used to form second conductors 202.

Conductive layer 416 may be formed from any suitable conductive material such as tungsten, another suitable metal, heavily doped semiconductor material, a conductive silicide, a conductive silicide-germanide, a conductive germanide, or the like deposited by any suitable method (e.g., CVD, PVD, etc.). Other conductive layer materials may be used. Barrier layer and/or adhesion layer 414 may include titanium nitride or another suitable layer such as tantalum nitride, tungsten nitride, tungsten, molybdenum, combinations of one or more layers, or any other suitable material(s). The deposited conductive layer 416 and barrier and/or adhesion layer 414 may be patterned and etched to form second conductors 202. In at least one embodiment, second conductors 202 are substantially parallel, substantially coplanar conductors that extend in a different direction than first conductors 200.

In other embodiments of the invention, second conductors 202 may be formed using a damascene process in which a dielectric layer is formed, patterned and etched to create openings or voids for conductors 202. The openings or voids may be filled with adhesion layer 414 and conductive layer 416 (and/or a conductive seed, conductive fill and/or barrier layer if needed). Adhesion layer 414 and conductive layer 416 then may be planarized to form a planar surface.

Following formation of second conductors 202, the resultant structure may be annealed to crystallize the deposited semiconductor material of diodes 104 (and/or to form silicide regions by reaction of silicide-forming metal layer 304 with p+ region 104c). The lattice spacing of titanium silicide and cobalt silicide are close to that of silicon, and it appears that silicide layers may serve as “crystallization templates” or “seeds” for adjacent deposited silicon as the deposited silicon crystallizes (e.g., a silicide layer enhances the crystalline structure of silicon diode 104 during annealing at temperatures of about 600-800° C.). Lower resistivity diode material thereby is provided. Similar results may be achieved for silicon-germanium alloy and/or germanium diodes.

Thus in at least one embodiment, a crystallization anneal may be performed for about 10 seconds to about 2 minutes in nitrogen and/or hydrogen at a temperature of about 600 to 800° C., and more preferably between about 650 and 750° C. Other annealing times, temperatures and/or environments may be used. In some embodiments, H2 and N2 may be used in a 1:1 ratio, more generally in a ratio from about 1:1 to about 1:4. Other ratios may be used.

Persons of ordinary skill in the art will understand that alternative memory cells in accordance with this invention may be fabricated by other similar techniques.

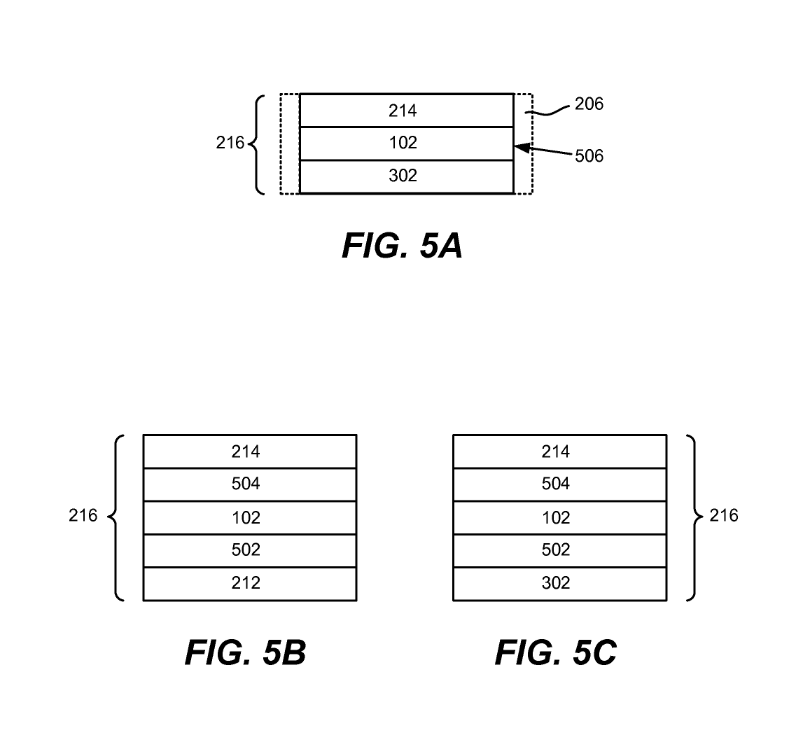

FIGS. 5A-C illustrate alternative embodiments for MIM stack 216 for any of the embodiments of FIGS. 2A-4G. With reference to FIG. 5A, in some embodiments, barrier layer 212 may be eliminated and C-based switching material 102 may be directly formed on silicide layer 302 (and/or silicide-forming metal 304). C-based switching material 102 may exhibit good adhesion to a metal silicide, and such a metal silicide may serve as the bottom electrode of MIM stack 216. Exemplary metal silicides include titanium silicide, cobalt silicide or the like. Such a metal silicide layer may also help seal hydrogen within the DLC, C-based switching material 102.

In some embodiments, a tungsten nitride adhesion and/or metal diffusion barrier may be used on top of C-based switching material 102 (in addition to or as top barrier layer 214). Such a tungsten nitride layer may exhibit good adhesion with C-based switching material 102 and help seal hydrogen within C-based switching material 102. PVD tungsten and CVD tungsten have high compressive stress and good adhesion to amorphous carbon, and may be similarly used as, with, or in place of barrier layer 214 or as a bottom electrode or bottom adhesion layer (e.g., as W, WN or a W/WN layer stack).

FIG. 5B illustrates an embodiment for MIM stack 216 in which C-based switching material 102 includes a bottom adhesion layer 502 between C-based switching material 102 and barrier layer 212, and a top adhesion layer 504 between C-based switching material 102 and barrier layer 214. In some embodiments, only one of the top and bottom adhesion layers 502 or 504 may be employed. FIG. 5C illustrates a similar embodiment for MIM stack 216 in which barrier layer 212 is eliminated and bottom adhesion layer 502 makes direct contact with silicide layer 302.

Top and bottom adhesion layers 502 and/or 504 may include any suitable adhesion layer(s) such as a conductive nitride, a conductive carbon nitride, tungsten nitride, a conductive silicide, tungsten silicide, and titanium silicide, dense (and in some cases compressive) polycrystalline graphitic carbon, or the like.

Increasing the density of a C-based film has also been found to improve adhesion of the film to other materials such as conductive layers. For example, polycrystalline graphitic carbon has high density and is conductive. In some embodiments, a C-based interface layer 502 or 504 is formed with an increased density relative to C-based switching material 102 to which C-based interface layer 502 or 504 is coupled. Reducing deposition rate during C-based layer formation may increase layer density. Reduction of the deposition rate of a C-based interface layer 502 or 504 may occur due to dilution of the precursors used during C-based interface layer formation.

In another embodiment of the invention, adhesion between C-based switching material 102 and barrier layer 212 and/or 214 may be increased with a C-based interface layer 502 and/or 504 formed by nitridizing a C-based material layer. A portion of C-based switching material 102 itself may be nitridized to form C-based interface layer 502 or 504, or a separate C-based material layer 502 or 504 adjacent C-based switching material 102 may be nitridized to form C-based interface layer 502 or 504.

For example, a C-based switching material 102 may be nitridized by exposing C-based switching material 102 to N₂, or any other N-containing gas (NH₃, N₂O or the like) at an elevated temperature, by plasma nitridizing in a PECVD chamber, or the like. Similarly, to improve the adhesion of C-based switching material 102 with an underlying metal layer, the underlying metal layer may be nitridized using N₂, or any other N-containing gas, before deposition of C-based switching material 102 over the metal layer.

In other embodiments of the invention, C-based interface layer 502 and/or 504 may be formed from a conductive polycrystalline carbon layer. Such layers may have high compressive stress, good adhesion between DLC and metal layers, high temperature thermal (e.g., structural and/or chemical) stability and serve as conductors without switching. Further, such films may be dense, thereby more effectively sealing hydrogen within C-based switching material 102. Additionally, polycrystalline carbon layers may have low resistivities (e.g., be sp² bond dominated with resistivities of not more than about 0.1 ohm-cm in some embodiments) and serve as current spreading layers that may reduce localized heating of other metals layers within a memory element.

In general, conductive polycrystalline carbon layers may be used as interface layers with other C-based switching materials such as graphitic carbon with or without filler material, amorphous carbon containing nanocrystalline graphene, silicon carbide, boron carbide and other crystalline forms of carbon. Such conductive polycrystalline carbon layers also may be used as interface layers for metal oxides, chalcogenides, or other resistivity-switching materials. Accordingly, in some embodiments of the invention, C-based switching material 102 may comprise one or more of the above-mentioned switching materials.

Exemplary thicknesses for such polycrystalline carbon layers range from about 50-200 angstroms, more generally from about 50-600 angstroms. Other thicknesses may be used. Table 4 provides PECVD process details for an exemplary conductive polycrystalline carbon adhesion layer formation process. Other precursors, flow rates, pressures, temperatures, powers and/or spacings may be used. Other deposition methods also may be used, such as LPCVD.

TABLE 4
EXEMPLARY PROCESS PARAMETERS
FOR POLYCRYSTALLINE CARBON ADHESION LAYER

| PROCESS PARAMETER | BROAD RANGE | NARROW RANGE |
|---|---|---|
| He:CₓH_{y} Ratio | 1:1-50:1 | 10:1-50:1 |
| PRESSURE (Torr) | 0.8-10 | 3-8 |
| SUBSTRATE TEMP (° C.) | 450-700 | 550-650 |
| TARGET RF POWER | 0.5-40 | 1-15 |
| (WATTS/IN²) | | |
| TARGET-SUBSTRATE | 250-550 | 350-450 |
| SPACING (mils) | | |

In some embodiments, barrier layer 212 may be eliminated and adhesion layer 502 may be in direct contact with silicide layer 302 (or silicide-forming metal 304).

In yet other embodiments, barrier layers 212 and/or 214 and/or adhesion layers 502 and/or 504 may be degenerately doped silicon, silicon germanium or a similar material. For example, degenerately doped silicon may have a doping concentration of greater than about 1×10²¹ ions/cm², more generally greater than about 1×10²⁰ ions/cm². Other doping concentrations may be used.

In one or more embodiments, C-based interface layer 502 and/or 504 may have a thickness of about 50 to about 600 angstroms, more preferably about 50 to about 200 angstroms. C-based switching material 102 may have a thickness of about 10 to about 600 angstroms, preferably about 10 to about 100 angstroms. Other thickness ranges may be used for these layers.

With reference to FIG. 5A, in some embodiments, all or a portion of a sidewall 506 of MIM stack 216 may have a compressive dielectric liner 206 formed thereon.

In some embodiments in accordance with this invention, following formation of C-based switching material 102, an anneal step may be performed prior to depositing additional material. In particular, the anneal may be performed in a vacuum or the presence of one or more forming gases, at a temperature in the range from about 350° C. to about 900° C., for about 30 to about 180 minutes. The anneal preferably is performed in about an 80%(N₂):20%(H₂) mixture of forming gases, at about 625° C. for about one hour.

Suitable forming gases may include one or more of N₂, Ar, and H₂, whereas preferred forming gases may include a mixture having above about 75% N₂ or Ar and below about 25% H₂. Alternatively, a vacuum may be used. Suitable temperatures may range from about 350° C. to about 900° C., whereas preferred temperatures may range from about 585° C. to about 675° C. Suitable durations may range from about 0.5 hour to about 3 hours, whereas preferred durations may range from about 1 hour to about 1.5 hours. Suitable pressures may range from about 11 to about 760 T, whereas preferred pressures may range from about 300 T to about 600 T.

A queue time of preferably about 2 hours between the anneal and the deposition of additional layers preferably accompanies the use of the anneal. A ramp up duration may range from about 0.2 hours to about 1.2 hours and preferably is between about 0.5 hours and 0.8 hours. Similarly, a ramp down duration also may range from about 0.2 hours to about 1.2 hours and preferably is between about 0.5 hours and 0.8 hours.

Although not wanting to be bound by any particular theory, it is believed that carbon-based switching material may absorb water from the air over time. Likewise, it is believed that the moisture may increase the likelihood of de-lamination of the carbon-based switching material. In some cases, it also might be acceptable to have a queue time of 2 hours from the time of deposition of carbon-based switching material to deposition of additional layers, skipping the anneal altogether.

Incorporation of such a post-carbon-formation-anneal preferably takes into account other layers of the memory cell, because these other memory cell layers will also be subject to the anneal. For example, the anneal may be omitted or its parameters may be adjusted where the aforementioned preferred anneal parameters would damage the other memory cell layers. The anneal parameters may be adjusted within ranges that result in the removal of moisture without damaging the layers of the annealed memory cell.

For instance, the temperature may be adjusted to stay within an overall thermal budget of a memory cell being formed. Likewise, any suitable forming gases, temperatures and/or durations may be used that are appropriate for a particular memory cell. In general, such an anneal may be used with any carbon-based switching material, such as CNT material, graphite, graphene, amorphous carbon, amorphous DLC, silicon carbide, boron carbide and other crystalline forms of carbon.

The foregoing description discloses only exemplary embodiments of the invention. Modifications of the above disclosed apparatus and methods which fall within the scope of the invention will be readily apparent to those of ordinary skill in the art. For instance, other pillar shapes may be used. Any suitable material may be used for conductors 200 and 202 such as copper, aluminum or other conductive layers. Further, hydrogen outgassing and sp³ to sp² bond conversion within DLC switching material 102 may be reduced by reducing anneal temperature (e.g., from 750° C. to 650° C. or 550° C. if possible).

In some embodiments, following a high temperature anneal for diode 104, compressive dielectric liner 206 may be removed (stripped). In other embodiments, dielectric liner 206 may remain.

Placing the C-based switching material 102 below diode 104 may increase compressive stress on the C-based switching material 102 (as the compressive stress of the entire stack in placed on the C-based switching material 102).

As device geometries shrink, use of a compressive dielectric sidewall liner 206 results in a larger effective decrease in cross-sectional area of the C-based switching material 102. The reduced cross-sectional area increases the effective resistance of the C-based switching material, making the C-based switching material more compatible with the selection (steering) device used during switching of the C-based material.

Accordingly, although the present invention has been disclosed in connection with exemplary embodiments thereof, it should be understood that other embodiments may fall within the spirit and scope of the invention, as defined by the following claims.

The invention claimed is:

1. A method of forming a memory cell having a diamond like carbon (“DLC”) resistivity-switching material, the method comprising:
forming a metal-insulator-metal (“MIM”) stack, the MIM stack including:
a first conductive layer;
a DLC switching layer above the first conductive layer; and
a second conductive layer above the DLC switching layer;
forming a compressive dielectric liner along a sidewall of the MIM stack; and
forming a steering element coupled to the MIM stack.

2. The method of claim 1, wherein at least one of the first and second conductive layers comprises a metal barrier layer.

3. The method of claim 1, wherein at least one of the first and second conductive layers comprises compressive degenerately doped silicon.

4. The method of claim 1, wherein the MIM stack further includes an adhesion layer positioned between at least one of the first conductive layer and the DLC switching layer and the second conductive layer and the DLC switching layer.

5. The method of claim 4, wherein the adhesion layer comprises conductive polycrystalline carbon.

6. The method of claim 4, wherein the adhesion layer comprises one or more of a conductive nitride, a conductive carbon nitride, tungsten nitride, a conductive silicide, tungsten silicide, and titanium silicide.

7. The method of claim 1, wherein the first conductive layer comprises a metal silicide.

8. The method of claim 1, wherein at least one of the first conductive layer, the second conductive layer and the DLC switching layer is under compressive stress.

9. The method of claim 1, wherein the DLC switching layer has a hydrogen content of about 0-50%.

10. The method of claim 1, wherein the compressive dielectric liner comprises silicon nitride.

11. The method of claim 1, wherein the compressive dielectric liner has a hydrogen content of at least 40 atm %.

12. The method of claim 1, further comprising depositing a compressive dielectric gap fill material around the MIM stack.

13. The method of claim 12, wherein the compressive dielectric gap fill material comprises silicon dioxide.

14. The method of claim 1, wherein forming the steering element coupled to the MIM stack comprises forming a polycrystalline semiconductor diode in series with the MIM stack.

15. A memory cell formed by the method of claim 1.

16. A method of forming a memory cell, the method comprising:
forming a metal-insulator-metal (“MIM”) stack, the MIM stack including:
a first conductive layer;
a diamond like carbon (“DLC”) switching layer above the first conductive layer; and
a second conductive layer above the DLC switching layer;
forming a compressive dielectric liner along a sidewall of the MIM stack;
forming compressive dielectric gap fill material around the MIM stack; and
forming a steering element coupled to the MIM stack.

17. The method of claim 16, wherein the compressive dielectric liner and compressive dielectric gap fill material surround the steering element.

18. A memory cell formed by the method of claim 16.

19. A memory cell comprising:
a metal-insulator-metal (“MIM”) stack including:
a first conductive layer;
a diamond like carbon (“DLC”) switching layer above the first conductive layer; and
a second conductive layer above the DLC switching layer;
a compressive dielectric liner along a sidewall of the MIM stack; and
a steering element coupled to the MIM stack.

20. The memory cell of claim 19, wherein at least one of the first and second conductive layers comprises a metal barrier layer.

21. The memory cell of claim 19, wherein at least one of the first and second conductive layers comprises compressive degenerately doped silicon.

22. The memory cell of claim 19, wherein the MIM stack further comprises an adhesion layer positioned between at least one of the first conductive layer and the DLC switching layer and the second conductive layer and the DLC switching layer.

23. The memory cell of claim 22, wherein the adhesion layer comprises polycrystalline conductive carbon.

24. The memory cell of claim 22, wherein the adhesion layer comprises one or more of a conductive nitride, a conductive carbon nitride, tungsten nitride, a conductive silicide, tungsten silicide, and titanium silicide.

25. The memory cell of claim 19, wherein the first conductive layer comprises a metal silicide.

26. The memory cell of claim 19, wherein at least one of the first conductive layer, the second conductive layer and the DLC switching layer is under compressive stress.

27. The memory cell of claim 19, wherein the DLC switching layer has a hydrogen content of about 0-50%.

28. The memory cell of claim 19, wherein the compressive dielectric liner has a hydrogen content of at least 40 atm %.

29. The memory cell of claim 19, further comprising a compressive dielectric gap fill material disposed around the MIM stack.

30. The memory cell of claim 19, wherein the steering element comprises a polycrystalline semiconductor diode in series with the MIM stack.

31. A memory cell comprising:
a metal-insulator-metal (“MIM”) stack, the MIM stack including:
a first conductive layer;
a diamond like carbon (“DLC”) switching layer above the first conductive layer; and
a second conductive layer above the DLC switching layer;
a compressive dielectric liner along a sidewall of the MIM stack;
a compressive dielectric gap fill material around the MIM stack; and
a steering element coupled to the MIM stack.

32. The memory cell of claim 31, wherein the compressive dielectric liner and compressive dielectric gap fill material surround the steering element.

33. A method comprising:
forming a metal-insulator-metal (“MIM”) stack by:
forming a first conductive layer;
forming a diamond like carbon (“DLC”) switching layer above the first conductive layer; and
forming a second conductive layer above the DLC switching layer; and
forming a compressive dielectric liner along a sidewall of the MIM stack.

34. The method of claim 33, further comprising forming compressive dielectric gap fill material around the MIM stack.

35. The method of claim 33, wherein at least one of the first and second conductive layers comprises a metal barrier layer.

36. The method of claim 33, further comprising forming an adhesion layer positioned between at least one of the first conductive layer and the DLC switching layer and the second conductive layer and the DLC switching layer.

37. The method of claim 33, wherein the first conductive layer comprises a metal silicide.

38. The method of claim 33, wherein the compressive dielectric liner has a hydrogen content of at least 40 atm %.

39. Apparatus comprising:
a metal-insulator-metal (“MIM”) stack comprising:
a first conductive layer;
a diamond like carbon (“DLC”) switching layer above the first conductive layer; and
a second conductive layer above the DLC switching layer; and
a compressive dielectric liner along a sidewall of the MIM stack.

40. The apparatus of claim 39, further comprising a compressive dielectric gap fill material around the MIM stack.

41. The apparatus of claim 39, wherein at least one of the first and second conductive layers comprises a metal barrier layer.

42. The apparatus of claim 39, further comprising an adhesion layer positioned between at least one of the first conductive layer and the DLC switching layer and the second conductive layer and the DLC switching layer.

43. The apparatus of claim 39, wherein the first conductive layer comprises a metal silicide.

44. The apparatus of claim 39, wherein the compressive dielectric liner has a hydrogen content of at least 40 atm %.
